(19) United States
(12) Patent Application Publication
(10) Pub. No.: US 2020/0170135 A1
(43) Pub. Date: May 28, 2020

(54) GASKET AND ELECTRONIC APPARATUS

(71) Applicant: FUJITSU LIMITED, Kawasaki-shi (JP)

(72) Inventor: TADASHI TATENO, Kawasaki (JP)

(73) Assignee: FUJITSU LIMITED, Kawasaki-shi (JP)

(21) Appl. No.: 16/679,384

(22) Filed: Nov. 11, 2019

(30) Foreign Application Priority Data
Nov. 28, 2018 (JP) 2018-222420

(51) Int. Cl. H05K 5/06

(52) U.S. Cl. CPC H05K 5/061

(57) ABSTRACT

A gasket includes a cavity provided within the gasket, and a convex and a concave included in an inner surface of the gasket and configured to contact with the cavity so as to face with each other along a direction in which the gasket is sandwiched.

### CROSS-REFERENCE TO RELATED APPLICATION

This application is based upon and claims the benefit of priority of the prior Japanese Patent Application No. 2018-222420, filed on Nov. 28, 2018, the entire contents of which are incorporated herein by reference.

### FIELD

The present disclosure relates to a gasket and an electronic device.

### BACKGROUND

In the related art, there is an electronic device in which electronic devices are accommodated in a container having an opening, and the opening of the container is closed by a cover member. In such an electronic device, an elastic gasket is used to secure a sealing performance between the cover member and the container. That is, the elastic gasket is provided on an edge of the container, and the container is closed by the cover member by sandwiching the gasket between the cover member and the container. For example, a hollow gasket having a cavity therein has been proposed as the gasket.

Related techniques are disclosed in, for example, Japanese Laid-open Utility Model Publication No. 01-037026.

### SUMMARY

According to an aspect of the embodiments, a gasket includes a cavity provided within the gasket, and a convex and a concave included in an inner surface of the gasket and configured to contact with the cavity so as to face with each other along a direction in which the gasket is sandwiched.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed,

### BRIEF DESCRIPTION OF DRAWINGS

FIG. 1 is a perspective view illustrating an exemplary configuration of an electronic device according to an embodiment;

FIG. 2 is a schematic cross-sectional view illustrating an exemplary configuration of a gasket according to the embodiment;

FIG. 3 is a view illustrating an example of a flow of sandwiching the gasket according to the embodiment between a cover member and a container;

FIG. 4 is a view illustrating an example of the flow of sandwiching the gasket according to the embodiment between the cover member and the container;

FIG. 5 is a view illustrating an example of the flow of sandwiching the gasket according to the embodiment between the cover member and the container;

FIG. 6 is a view illustrating an example of a configuration of a gasket according to a first comparative example;

FIG. 7 is a view illustrating an example of a flow of sandwiching the gasket according to the first comparative example between a cover member and a container;

FIG. 8 is a view illustrating an example of a configuration of a gasket according to a second comparative example;

FIG. 9 is a view illustrating an example of a flow of sandwiching the gasket according to the second comparative example between a cover member and a container;

FIG. 10 is a view illustrating an example of a flow of sandwiching the gasket according to the second comparative example between the cover member and the container; and

FIG. 11 is a view illustrating an example of a relationship between a displacement amount of the cover member and a force acting on the cover member.

### DESCRIPTION OF EMBODIMENTS

When a hollow gasket having a cavity therein is used and when the gasket is sandwiched between a cover member and a container, a buckling may occur on an inner wall surface on the cavity side of the gasket. When a buckling occurs on the inner wall surface on the cavity side of the gasket, the material of the gasket fatigues and the gasket tends to be bent. As a result, the sealing performance between the cover member and the container sandwiching the gasket therebetween may be impaired.

Hereinafter, embodiments of a technology capable of improving the sealing performance between two members sandwiching the gasket therebetween will be described in detail with reference to the accompanying drawings. The disclosed technology is not limited by the embodiments. In addition, in the embodiments, components having similar functions will be denoted by common reference numerals, and overlapping descriptions thereof will be omitted.

### Embodiment

### [Configuration of Electronic Device]

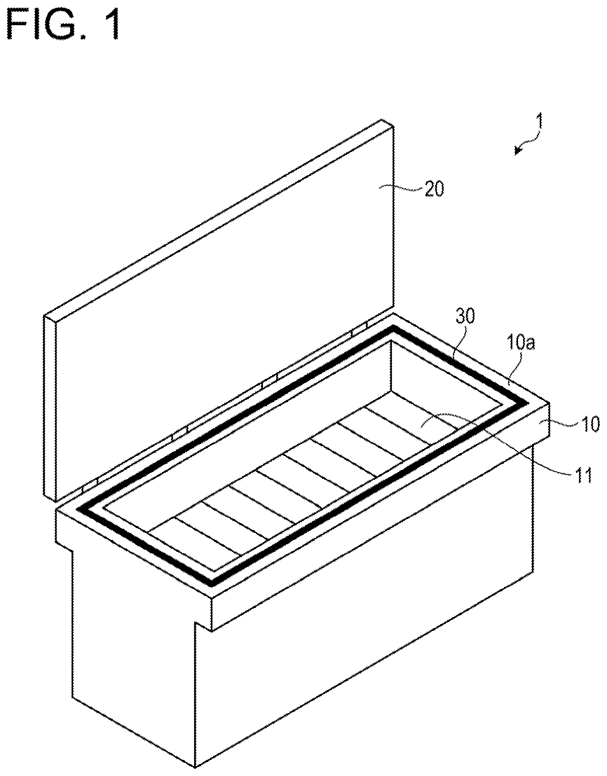

FIG. 1 is a perspective view illustrating an exemplary configuration of an electronic apparatus 1 according to an embodiment. The electronic apparatus 1 illustrated in FIG. 1 includes a container 10, a cover member 20, and a gasket 30.

The container 10 has a space for accommodating electronic devices 11. The electronic devices 11 are, for example, information and communication technology (ICT) devices. An opening is formed on the top of the container 10, and carry-in and carry-out of the electronic devices 11 are performed through the opening.

The cover member 20 is rotatably mounted on the container 10, and opens/closes the opening of the container 10. The cover member 20 closes the opening of the container 10 by being pressed on the container 10 side by, for example, a clamp or the like.

The gasket 30 is provided on an edge 10a of the container 10 surrounding the opening. That is, the gasket 30 is mounted on a groove formed on the edge 10a of the container 10. The gasket 30 has elasticity, and is compressed by being sandwiched between the cover member 20 and the container 10 (i.e., the edge 10a of the container 10) when the cover member 20 closes the opening of the container 10. The container 10 is sealed by the cover member 20 by sandwiching the gasket 30 between the cover member 20 and the container 10.

### [Configuration of Gasket]

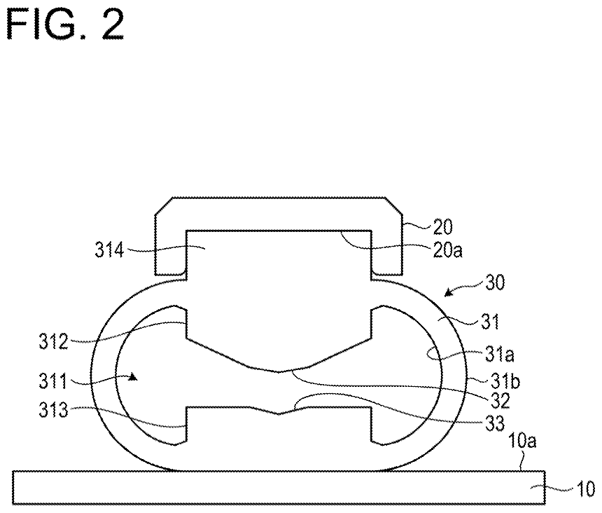

FIG. 2 is a schematic cross-sectional view illustrating an exemplary configuration of the gasket 30 according to the embodiment. FIG. 2 illustrates a state where the gasket 30 provided on the edge 10a of the container 10 is in contact with the cover member 20. For the convenience of explanation, the container 10 and the cover member 20 are partially illustrated in FIG. 2. The gasket 30 includes a gasket body 31, a convex portion 32, and a concave portion 33.

The gasket body 31 has a cavity 311 therein to be formed in a circular shape or an elliptical shape in cross-sectional view. Since the cavity 311 is formed inside the gasket body 31, the elasticity of the gasket 30 is reduced by an amount corresponding to the cavity 311, so that the force acting on the cover member 20 and the container 10 from the gasket 30 is reduced. As a result, deformation of the cover member 20 and the container 10 is suppressed as compared with a configuration in which the cavity 311 is not formed inside the gasket body 31.

The convex portion 32 and the concave portion 33 are formed on an inner wall surface 31a on the cavity 311 side of the gasket body 31 to face with each other along a direction in which the gasket body 31 is sandwiched between the cover member 20 and the container 10 (i.e., vertical direction in FIG. 2). That is a pair of raised portions 312 and 313 are formed on the inner wall surface 31a of the gasket body 31 to face each other along the vertical direction in FIG. 2, and the convex portion 32 is formed on the upper side raised portion 312 among the pair of raised portions 312 and 313 of the gasket body 31. In addition, the concave portion 33 is formed on the lower side raised portion 313 among the pair of raised portions 312 and 313 of the gasket body 31.

When the gasket body 31 is not sandwiched between the cover member 20 and the container 10, the convex portion 32 and the concave portion 33 face with each other with a predetermined space. Then, when the gasket body 31 is sandwiched between the cover member 20 and the container 10, the convex portion 32 and the concave portion 33 approach with each other and engage with each other according to the elastic deformation of the gasket body 31.

Meanwhile, when a hollow gasket having the cavity 311 therein is used and when the gasket is sandwiched between the cover member 20 and the container 10, a buckling may occur on the inner wall surface 31a on the cavity 311 side of the gasket. When a buckling occurs on the inner wall surface 31a on the cavity 311 side of the gasket, the material of the gasket fatigues and the gasket tends to be bent. As a result, the sealing performance between the cover member 20 and the container 10 sandwiching the gasket therebetween may be impaired.

Accordingly, in the gasket 30 of the present embodiment, as illustrated in FIG. 2, the convex portion 32 and the concave portion 33 are formed on the inner wall surface 31a on the cavity 311 side of the gasket body 31 so as to face with each other along the direction in which the gasket body 31 is sandwiched between the cover member 20 and the container 10. As a result, when the gasket body 31 is sandwiched between the cover member 20 and the container 10, the convex portion 32 and the concave portion 33 approach with each other and engage with each other according to the elastic deformation of the gasket body 31. As the convex portion 32 and the concave portion 32 engaging with each other, the load acting on the inner wall surface 31a on the cavity 311 side of the gasket body 31 is distributed to the convex portion 32 and the concave portion 33, so that the occurrence of buckling on the inner wall surface 31a is suppressed. As a result, the seal performance between the cover member 20 and the container 10 sandwiching the gasket 30 therebetween may be improved.

In addition, the convex portion 32 has a shape that narrows in width toward the concave portion 33. Meanwhile, the concave portion 33 has a shape that widens in width toward the convex portion 32. As a result, when the convex portion 32 and the concave portion 33 are in contact with each other, the convex portion 32 is guided to a central portion of the concave portion 33. Thus, the reliability of the engagement between the convex portion 32 and the concave portion 33 is improved. Accordingly, the sealing performance between the cover member 20 and the container 10 may be further improved.

In addition, a raised portion 314 is formed in a region of an outer wall surface 31b of the gasket body 31, corresponding to the convex portion 32. Meanwhile, a groove portion 20a is formed in a region of the cover member 20 corresponding to the raised portion 314. Then, the raised portion 314 of the gasket body 31 is engaged with the groove portion 20a formed in the cover member 20, when the gasket body 31 is sandwiched between the cover member 20 and the container 10. As a result, the positional deviation of the gasket body 31 with respect to the cover member 20 is suppressed, and accordingly, the seal performance between the cover member 20 and the container 10 may be further improved.

### [Action and Effect]

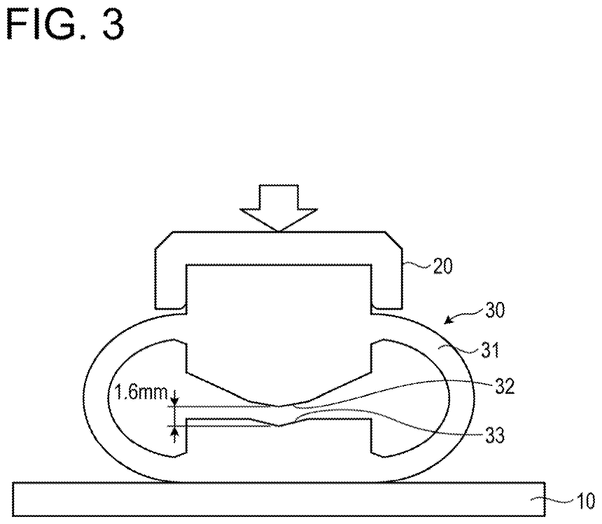

Next, an action and an effect of the gasket 30 according to the present embodiment will be described. FIGS. 3 to 5 are views for explaining an example of a flow of sandwiching the gasket 30 according to the embodiment between the cover member 20 and the container 10. FIG. 3 illustrates an initial state where a pressing force is applied to the cover member 20. In the initial state, the convex portion 32 and the concave portion 33 face with each other with a space of, for example, 1.6 mm. The pressing force is applied by, for example, a clamp or the like. In FIG. 3, the pressing force applied to the cover member 20 is indicated by a white arrow. The cover member 20 is displaced toward the container 10 by applying the pressing force to the cover member 20. Elastic deformation of the gasket body 31 occurs by displacing the cover member 20, and the convex portion 32 and the concave portion 33 approach with each other and engage with each other according to the elastic deformation of the gasket body 31.

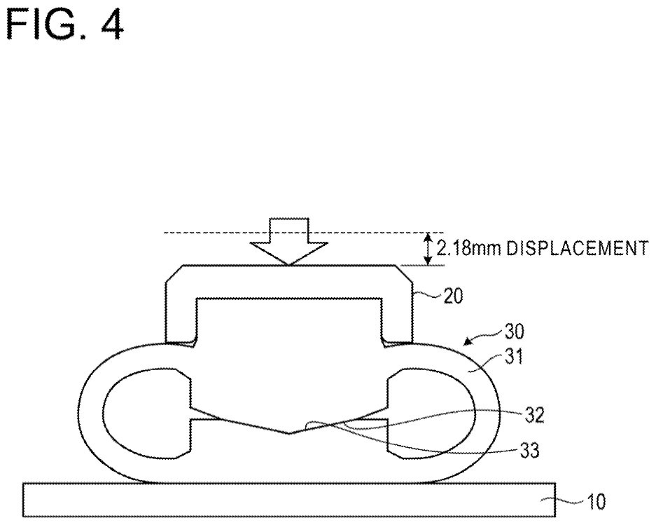

FIG. 4 illustrates a state where the cover member 20 is displaced toward the container 10. In the example in FIG, 4, the convex portion 32 and the concave portion 33 engage with each other when the cover member 20 is displaced by, for example, 2.18 mm, As the convex portion 32 and the concave portion 32 engage with each other, the load acting on the inner wall surface 31a on the cavity 311 side of the gasket body 31 is distributed to the convex portion 32 and the concave portion 33, so that the occurrence of buckling on the inner wall surface 31a is suppressed. In addition, the convex portion 32 presses the concave portion 33, and thus, a region of the outer wall surface 31b of the gasket body 31, which corresponds to the concave portion 33, is in close contact with the container 10. As a result, the contact area between the gasket body 31 and the container 10 may be increased.

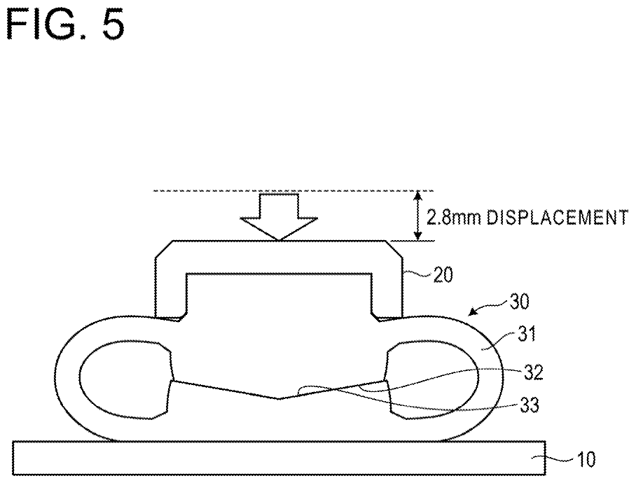

FIG. 5 illustrates a state where the cover member 20 is further displaced toward the container 10. In the example in FIG, 5, the cover member 20 is displaced by, for example, 2.8 mm. In this state, the engagement between the convex portion 32 and the concave portion 33 is maintained, and thus, the occurrence of the buckling on the inner wall surface 31a is suppressed. In addition, the convex portion 32 presses the concave portion 33, and thus, the close contact between the region of the outer wall surface 31b of the gasket body 31, which corresponds to the concave portion 33, and the container 10 is maintained.

As a result, in the gasket 30, when the gasket body 31 is sandwiched between the cover member 20 and the container 10, the occurrence of buckling on the inner wall surface 31a on the cavity 311 side of the gasket body 31 may be suppressed. As a result, the seal performance between the cover member 20 and the container 10 sandwiching the gasket 30 therebetween may be improved.

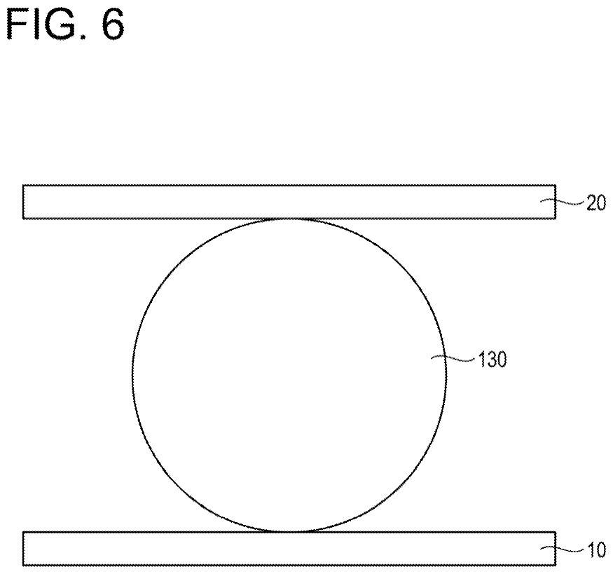

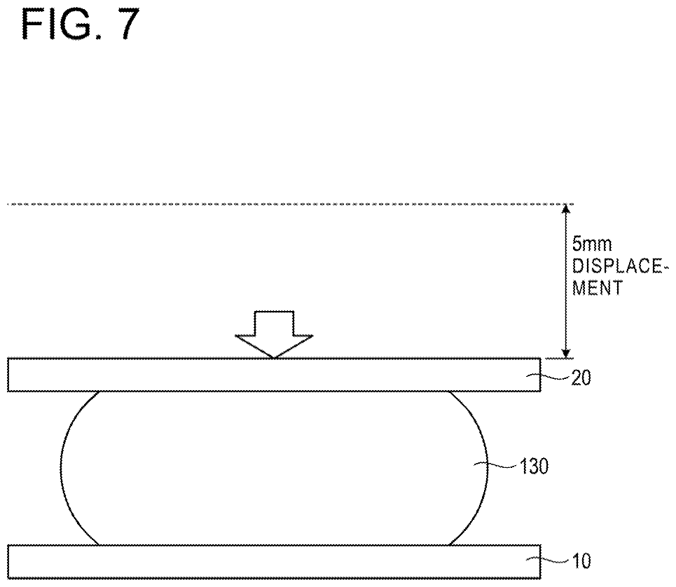

Here, an effect will be described using comparative examples. FIG. 6 is a view illustrating an example of a configuration of a gasket 130 according to a first comparative example. The gasket 130 illustrated in FIG. 6 does not have a cavity inside the gasket body. An outer diameter of the gasket 130 is, for example, 10 mm. FIG. 7 is a view for explaining an example of a flow of sandwiching the gasket 130 according to the first comparative example between the cover member 20 and the container 10. FIG. 7 illustrates a state where the cover member 20 is displaced toward the container 10. In the example in FIG. 7, the cover member 20 is displaced by, for example, 5 mm. When the cover member 20 is displaced, elastic deformation of the gasket 130 occurs, and the force acting on the cover member 20 and the container 10 from the gasket 130 is increased. In this manner, when the force acting on the cover member 20 and the container 10 from the gasket 130 is increased, the cover member 20 and the container 10 may be deformed.

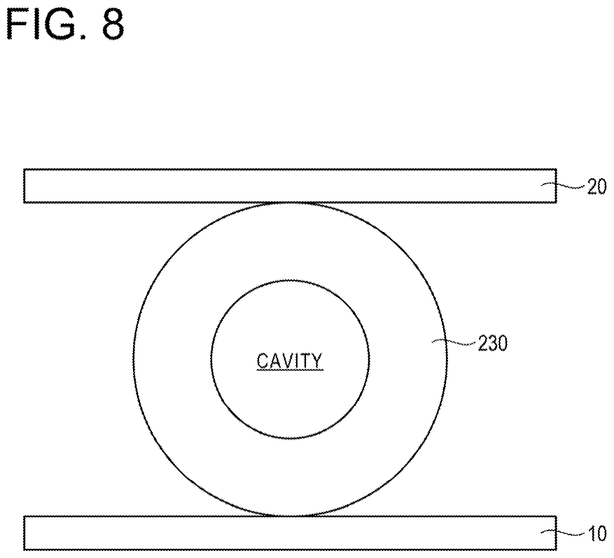

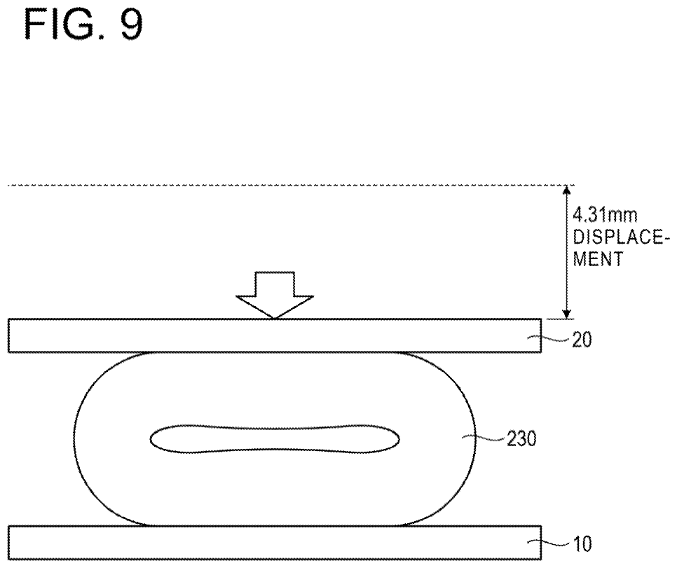

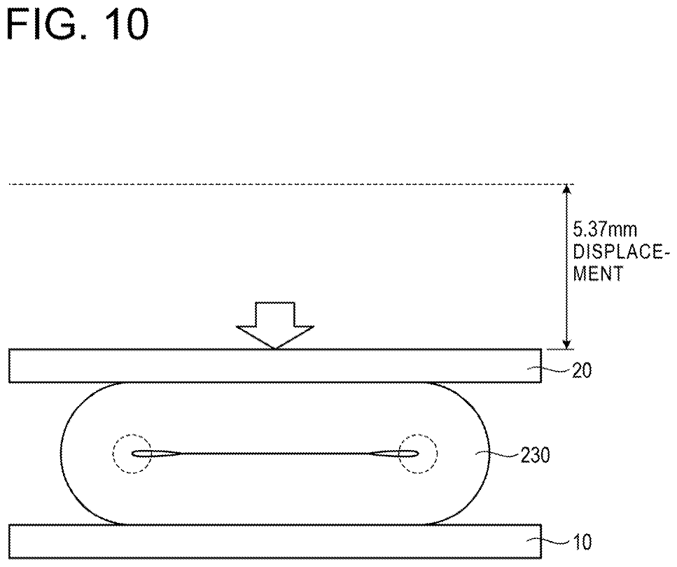

FIG. 8 is a view illustrating an example of a configuration of a gasket 230 according to a second comparative example. The gasket 230 illustrated in FIG. 8 has a cavity inside the gasket body. An outer diameter of the gasket 230 is, for example, 10 mm, and an inner diameter thereof is, for example, 5 mm. FIGS. 9 and 10 are views for explaining an example of a flow of sandwiching the gasket 230 according to the second comparative example between the cover member 20 and the container 10. FIG. 9 illustrates a state where the cover member 20 is displaced toward the container 10. In the example in FIG. 9, the cover member 20 is displaced by, for example, 4.31 mm. When the cover member 20 is displaced, elastic deformation of the gasket 230 occurs, and the force acting on the cover member 20 and the container 10 from the gasket 230 is increased. However, in the gasket 230 provided with the cavity therein, the elasticity of the gasket 230 is reduced by an amount corresponding to the cavity, so that the force acting on the cover member 20 and the container 10 from the gasket 230 is reduced. As a result, in the gasket 230, the deformation of the cover member 20 and the container 10 is suppressed as compared with the gasket 130 which does not have the cavity therein (see FIG. 6), FIG. 10 illustrates a state where the cover member 20 is displaced toward the container 10. In the example in FIG. 10, the cover member 20 is displaced by, for example, 5.37 mm. When the force applied to the gasket 230 from the cover member 20 exceeds the buckling load as the cover member 20 is displaced, a buckling occurs on the inner wall surface on the cavity side of the gasket 230. In FIG. 10, the portion where the buckling has occurred is indicated by a broken-line circle. The gasket 230 tends to be bent, and accordingly, the seal performance between the cover member 20 and the container 10 sandwiching the gasket 230 therebetween may be impaired.

Meanwhile, in the gasket 30 of the present embodiment, the convex portion 32 and the concave portion 33 are formed on the inner wall surface 31a on the cavity 311 side of the gasket body 31 so as to face with each other along the direction in which the gasket body 31 is sandwiched between the cover member 20 and the container 10. As a result, when the gasket body 31 is sandwiched between the cover member 20 and the container 10, the convex portion 32 and the concave portion 33 approach with each other and engage with each other according to the elastic deformation of the gasket body 31. As the convex portion 32 and the concave portion 32 engages with each other, the load acting on the inner wall surface 31a on the cavity 311 side of the gasket body 31 is distributed to the convex portion 32 and the concave portion 33, so that the occurrence of buckling on the inner wall surface 31a is suppressed. As a result, the seal performance between the cover member 20 and the container 10 sandwiching the gasket 30 therebetween may be improved.

[Relationship between Displacement Amount of Cover Member and Force acting on Cover Member]

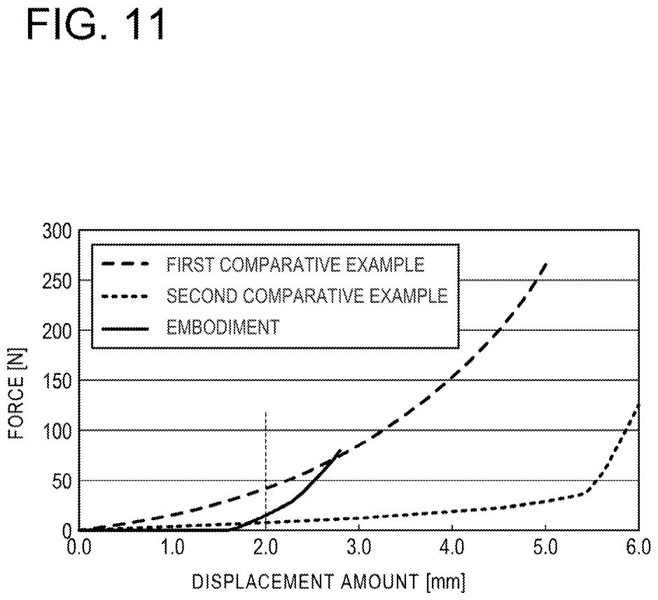

FIG. 11 is a view illustrating an example of a relationship between a displacement amount of the cover member 20 and a force acting on the cover member 20. FIG. 11 illustrates simulation results obtained by measuring the force acting on the cover member 20 by changing the displacement amount of the cover member 20. In FIG. 11, “FIRST COMPARATIVE EXAMPLE” is the simulation result corresponding to the gasket 130 of the first comparative example. In addition, “SECOND COMPARATIVE EXAMPLE” is the simulation result corresponding to the gasket 230 of the second comparative example. In addition, “EMBODIMENT” is the simulation result corresponding to the gasket 30 of the present embodiment.

As illustrated in FIG. 11, in the first comparative example, the force acting on the cover member 20 is approximately 40 N when the displacement amount of the cover member 20 is 2.0 mm, The force is a value higher than the upper limit value for preventing the deformation of the cover member 20.

In addition, in the second comparative example, the force acting on the cover member 20 is approximately 10 N when the displacement amount of the cover member 20 is 2.0 mm, The force is a value that is lower than the lower limit value for maintaining the sealing performance between the cover member 20 and the container 10. Here, in the second comparative example, the displacement amount of the cover member 20 may be set to be larger than 5 mm which is the inner diameter of the gasket 230, in order to maintain the sealing performance between the cover member 20 and the container 10. For example, the displacement amount of the cover member 20 may be set to be larger than 537 mm. However, the force applied to the gasket 230 from the cover member 20 increases as the displace amount of the cover member 20 increases. Thus, when the force applied to the gasket 230 from the cover member 20 exceeds the buckling load, a buckling occurs on the inner wall surface on the cavity side of the gasket 230.

In contrast, in the embodiment, the force acting on the cover member 20 is approximately 20 N when the displacement amount of the cover member 20 is 2.0 mm. The force is a value higher than the lower limit value for maintaining the sealing performance between the cover member 20 and the container 10 and lower than the upper limit for preventing the deformation of the cover member 20. In addition, in the embodiment, a buckling did not occur on the inner wall surface 31a on the cavity 311 side of the gasket body 31 even when the displacement amount of the cover member 20 is increased.

As described above, the gasket 30 according to the present embodiment includes the gasket body 31, the convex portion 32, and the concave portion 33. The gasket body 31 has the cavity 311 therein. The convex portion 32 and the concave portion 33 are formed on an inner wall surface 31a on the cavity 311 side of the gasket body 31 to face each other along a direction in which the gasket body 31 is sandwiched between the cover member 20 and the container 10. With the configuration of the gasket 30, the seal performance between the cover member 20 and the container 10 sandwiching the gasket 30 therebetween may be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A gasket comprising:
a cavity provided within the gasket; and
a convex and a concave included in an inner surface of the gasket and configured to contact with the cavity so as to face with each other along a direction in which the gasket is sandwiched.

2. The gasket according to claim 1,
wherein the convex has a shape that narrows in width toward the concave, and
wherein the concave has a shape that widens in width toward the convex.

3. The gasket according to claim 1, further comprising:
a pair of raised portions, in the inner surface, which face with each other along a direction in which the gasket is sandwiched,
wherein the convex is formed in a first raised portion of the pair of raised portions, and
wherein the concave is formed in a second raised portion of the pair of raised portions.

4. The gasket according to claim 1,
wherein, when the gasket is sandwiched without a pressing force to the gasket, the convex and the concave face with each other with a predetermined space, and
wherein, when the gasket is sandwiched with the pressing force to the gasket, the convex and the concave approach with each other and engage with each other according to elastic deformation of the gasket.

5. An electronic apparatus comprising:
a container configured to have a space to accommodate an electronic device and an opening formed at a top of the container,
a cover configured to open/close the opening of the container, and
a gasket provided over an edge of the container surrounding the opening, and configured to have elasticity and to be compressed by being sandwiched between the cover member and the container when the cover closes the opening,
wherein the gasket includes a cavity provided within the gasket, and a convex and a concave included in an inner surface of the gasket and configured to contact with the cavity so as to face with each other along a direction in which the gasket is sandwiched between the cover and the container.
